(19) United States
(12) Patent Application Publication
(10) Pub. No.: US 2007/0052556 A1
(43) Pub. Date: Mar. 8, 2007

(54) Adaptive filtering

(75) Inventors: Erwin Janssen, Eindhoven (DE); Derk Reefman, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V. GROENEWOUDSEWEG 1, 5621 BA EINDHOVEN (NL)

(21) Appl. No.: 10/552,771

(22) PCT Filed: Apr. 15, 2004
(86) PCT No.: PCT/IB04/50452

§ 371 Date: Oct. 12, 2005

(30) Foreign Application Priority Data
Apr. 17, 2003 (EP) 03101056.4

(51) Int. Cl. H03M 7/00

(52) U.S. Cl. 341/50

(57) ABSTRACT

An adaptive filtering device and method where at least one adaptive filter receives an input signal and a metering device receives an output of the at least one adaptive filter, monitors a characteristic of the output, such as power of high-frequency components, and forwards a correction signal in a feedback loop to adjust the characteristic of the at least one filter in order to change the characteristic of the output. An adaptive filtering device (200) and method where two low-pass FIR filters (202, 204) receive an input signal, a weighted adder (206) receives outputs from the two low-pass FIR filters and changes a weighting of each to produce filtered output data, and a controller (208) that receives a cutoff frequency (203), supplies the cut-off frequency to the two low-pass FIR filters, and supplies a signal to the weighted adder for varying the weighting of each of the low-pass FIR filters to switch therebetween.

### FIELD OF THE INVENTION

The present invention relates generally to adaptive filters and methods for performing the same and more specifically, to adaptive filters and methods for performing the same with improved outputs and/or with reduced computational complexity.

### DESCRIPTION OF THE RELATED ART

In the proposals for the Super Audio Compact Disc (SA-CD), a bit stream from a sigma-delta modulator (SDM), referred to as the direct stream digital (DSD) format is directly put on disc, as a 64 times oversampled one-bit signal, for example. Due to this feature, the bandwidth of SA-CD, in principle, exceeds 100 kHz, where from 0-20 kHz the Signal-to-Noise-Ratio (SNR) is high (about 120 dB), and from 20 kHz upwards, the SNR gradually decreases because of increased quantization.

This characteristic is schematically displayed in FIG. 1, where the solid line curve illustrates the conventional DSD spectrum without audio input signal. This increase in noise causes a potential problem in signal processing, which can easily be explained.

A small signal recorded in DSD may need to be amplified by a large factor. Because the DSD signal itself cannot be amplified (the DSD signal includes 1-bit words with value −1 and 1), the DSD signal needs to be converted to an intermediate format, amplified, and converted back to DSD. The conversion to the intermediate format is in principle a low-pass operation, where the output of the low-pass filter is a high-rate multi-bit signal. The amplification operation can be performed in the intermediate format. If a bandwidth of 100 kHz is to be retained, as discussed above, the filter characteristic shown by the dotted line in FIG. 1 can be used for the low-pass filtering. As is clear from FIG. 1, a significant amount of noise may still be present after the low-pass filtering (sometimes, the power in the noise region, 20-100 kHz, is more than that of the signal itself). After a gain factor has been applied to the intermediate signal, the original signal is amplified, and so is the noise signal. Finally, the amplified signal may be converted back to DSD. This operation involves feeding the intermediate high-rate multi-bit signal to an SDM.

This may cause two problems. First, the input values to an SDM cannot be arbitrarily large and thus there is a chance the SDM may be overloaded and become unstable when the amplified signal is input to the SDM. Since every requantization operation (to the intermediate format and back to the DSD format) adds some high-frequency noise, chances that an overload may occur increase with each signal processing operation performed. Once an overload has occurred, there is no way to restore the output.

Second, the SA-CD standard as defined in the Super-Audio CD System Description, Part 2, “Audio Specification”, also known as the Scarlet book, prescribes, in Annex D, the maximum amount of noise (RMS) which is allowed to be present in the band above 20 kHz. The maximum RMS value for the band between 40 kHz and 100 kHz is set in order to protect loudspeakers. Again, it is very possible that whereas the original signal might be Annex D compliant, an amplified version might not.

Conventionally, signal processing is performed until a problem is met, i.e., either the final disc is not Annex D compliant, or overloading of the SDM occurs. If a problem is detected, the entire process is repeated, but with different conversion filters. These new filters will filter out more high-frequency information, so that no problems will be encountered. The new filter characteristic could be, for example, the dashed line in FIG. 1.

This approach has clear drawbacks in that, if a mistake is discovered after a significant amount of processing has already been performed, it all must be re-done, and that low-pass filtering may be applied in some cases where it is not necessary—thus unnecessarily reducing the bandwidth of the intermediate signal (although it is noted that the bit-rate of the intermediate format will not change).

It is clear from the above, that requantization of a DSD signal is not a trivial task and that many problems may occur when requantizing. Two of these problems have been identified: overload of a SDM and generation of non-compliant SA-CD DSD streams.

As described above, filtering of signals is a common operation in digital signal processing (DSP) applications. Typically FIR filters are used because of the easy realizable linear phase response. In applications that deal with high-quality digital audio, such as SA-CD, a non-linear phase is not acceptable, so IIR filters are not used. However, if adaptive (low-pass) filtering is required, IIR filters are used because it is known how to change the cut-off frequency without clicks in the audio output for IIR filters. Phase correction techniques, which are expensive, can be applied, but a suitable or perfect linear phase response cannot be obtained. Furthermore, IIR filters are computationally expensive.

### SUMMARY OF THE INVENTION

An object of the invention is to present a solution that improves adaptive filtering. Other objects of the invention are to provide the ability to switch between different low-pass filters without introducing clicks or other distortions in the filtered output and/or to generate filter coefficients in an efficient way with reduced computational load.

To this end, the present invention provides an adaptive filtering device and method where at least one adaptive filter receives an input signal and a metering device receives an output of the at least one adaptive filter, monitors a characteristic of the output, such as power of high-frequency components, and forwards a correction signal in a feedback loop to adjust the characteristic.

The present invention further provides an adaptive filtering device where the adaptive filter is a low-pass filter, the metering device is a band-pass or high-pass filter and the characteristic is amount of high frequency power in the output and the correction signal raises or lowers the high frequency cut-off of the low-pass filter.

The present invention further provides an adaptive filtering device and method, where the adjusted characteristic is applied to the input signal block-by-block.

The present invention further provides a signal processing device including a signal processing unit with at least one input and at least one output and an adaptive filtering device for each of the at least one inputs and at least one outputs.

The present invention further provides a method of performing adaptive filtering, including receiving an output of at least one adaptive filter, monitoring a characteristic of the output, and forwarding a correction signal in a feedback loop to adjust the filter characteristic in order to adjust the output characteristic.

The present invention further provides a method of performing adaptive filtering, the at least one adaptive filter is a low-pass filter, and the characteristic is amount of high frequency in the output and the correction signal raises or lowers the high frequency cut-off of the low-pass filter.

To this end, the present invention also provides an adaptive filtering device and method where two low-pass FIR filters receive an input signal, a weighted adder receives outputs from the two low-pass FIR filters and changes a weighting of each to produce filtered output data, and a controller that receives a cut-off frequency, supplies the cut-off frequency to the two low-pass FIR filters, and supplies a signal to the weighted adder for varying the weighting of each of the low-pass FIR filters to switch therebetween.

The present invention further provides an adaptive filtering device where the varied weighting is applied block-by-block.

The present invention further provides an adaptive filtering device where the adaptive filter device operates in a normal mode and a transition mode. In the normal mode, the adaptive filter device does not switch filter characteristics and the output of the adaptive filter device is from only one of the at least two low-pass FIR filters. In the transition mode, the adaptive filter device switches filter characteristics and the output of the adaptive filter device is from more than one of the at least two low-pass FIR filters.

The present invention further provides that, in the transition mode, the controller calculates new filter coefficients and loads the new filter coefficients into an unused low-pass FIR filter, enables the unused low-pass FIR filter, varies the weighting between at least one of the low-pass FIR filters currently being used and the unused low-pass FIR filter to switch therebetween, and disables the at least one of the low-pass FIR filters currently being used.

The present invention further provides that the controller calculates the new filter coefficients by calculating initial sine and cosine values using an approximation formula and calculating coefficients using a sine prediction filter. The present invention further provides that the controller calculates coefficients using the sine prediction filter by applying a pre-calculated window function and normalizing the window for unity DC gain.

The present invention further provides a method of performing adaptive filtering, including receiving outputs from at least two low-pass FIR filters and changing a weighting of each to produce filtered output data and receiving at least one cut-off frequency, supplying the cut-off frequency to the at least two low-pass FIR filters, and varying the weighting of each of the at least two low-pass FIR filters to switch between at least two low-pass FIR filters.

The present invention further provides a method that operates in a normal mode and a transition mode. In the normal mode, the method does not switch filter characteristics and the output is from only one of the at least two low-pass FIR filters. In the transition mode, the method switches filter characteristics and the output is from more than one of the at least two low-pass FIR filters.

The present invention further provides that the transition mode includes calculating new filter coefficients and loading the new filter coefficients into an unused low-pass FIR filter, enabling the unused low-pass FIR filter, varying the weighting between at least one of the low-pass FIR filters currently being used and the unused low-pass FIR filter to switch therebetween, and disabling the at least one of the low-pass FIR filters currently being used.

The present invention further provides that calculating the new filter coefficients includes calculating initial sine and cosine values using an approximation formula, and calculating coefficients using a sine prediction filter.

The present invention further provides that calculating coefficients using the sine prediction filter includes applying a pre-calculated window function and normalizing the window for unity DC gain.

### BRIEF DESCRIPTION OF THE DRAWINGS

The present invention will become more fully understood from the detailed description given below and the accompanying drawings, which are given for purposes of illustration only, and thus do not limit the invention.

FIG. 1 illustrates a graph of a conventional DSD spectrum without audio input signal as the solid line curve and two filter characteristics usable for low-pass filtering, shown by the dotted line and the dashed line.

FIG. 2 illustrates an adaptive low-pass filtering device, in accordance with an exemplary embodiment of the present invention.

FIG. 3 illustrates a signal processing apparatus including a plurality of adaptive low-pass filtering devices, in accordance with an exemplary embodiment of the present invention.

FIG. 4 is a graph of the spectrum of a valid signal, obtained by adjusting the gain of a 1 kHz sine wave.

FIG. 5 is a graph of the spectrum of a DSD stream that has been generated from the signal shown in FIG. 4.

FIG. 6 is a graph of the spectrum of a DSD stream that has been generated with an adaptive low-pass filtering device, in accordance with an exemplary embodiment of the present invention.

FIG. 7 illustrates an adaptive low-pass filtering device, in accordance with another exemplary embodiment of the present invention.

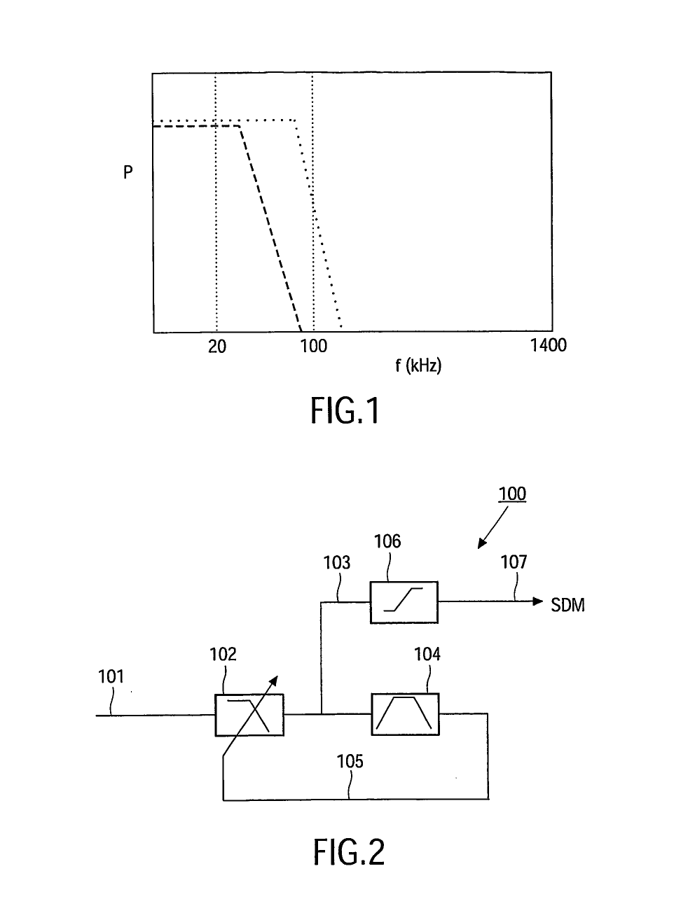

### DETAILED DESCRIPTION OF THE EXEMPLARY EMBODIMENTS

As is clear from the problems discussed in conventional solutions, it is important to control the signal energy in the high-frequency region. The basic idea to solve this, is to provide an active filtering operation in the signal path, which filters to such an extent that the total high-frequency signal power is maintained below a desired maximum or maxima.

FIG. 2 illustrates the structure of an adaptive low-pass filtering device 100, which accomplishes this objective, in accordance with an exemplary embodiment of the present invention. An incoming, intermediate, multi-bit stream 101, with full frequency range, generated by low-pass filtering at e.g. 100 kHz, passes through an adaptive low-pass filter 102. This stream 101 is exemplary, any other stream known to one of ordinary skill in the art could also be utilized.

The resulting output stream 103 is fed through a metering device, such as a band-pass or high-pass filter 104, which determines the power of the high frequency (HF) part of the signal 101. If the amount of HF is too large, a correction signal 105 is fed back to the adaptive low-pass filter 102 to reduce the cut-off frequency, thus reducing the amount of HF in the output signal 103. Conversely, if the amount of HF is too small, the correction signal 105 is fed back to the low-pass filter 102 to increase the cut-off frequency, thus increase the amount of HF in the output signal 103. This parameter, the high frequency (HF) part of the signal, is exemplary, any other parameter or parameters known to one of ordinary skill in the art could also be utilized.

The output stream 103 of the adaptive low-pass filter 102 may be passed through an optional clipper 106 to help ensure a downstream SDM will not be overloaded because of large peak values in the baseband. The output 107 of the adaptive low-pass filtering device 100 may be safely converted to DSD. If the desired maximum or maxima are set as the Annex D values, the output signal 107 will be compliant with Annex D.

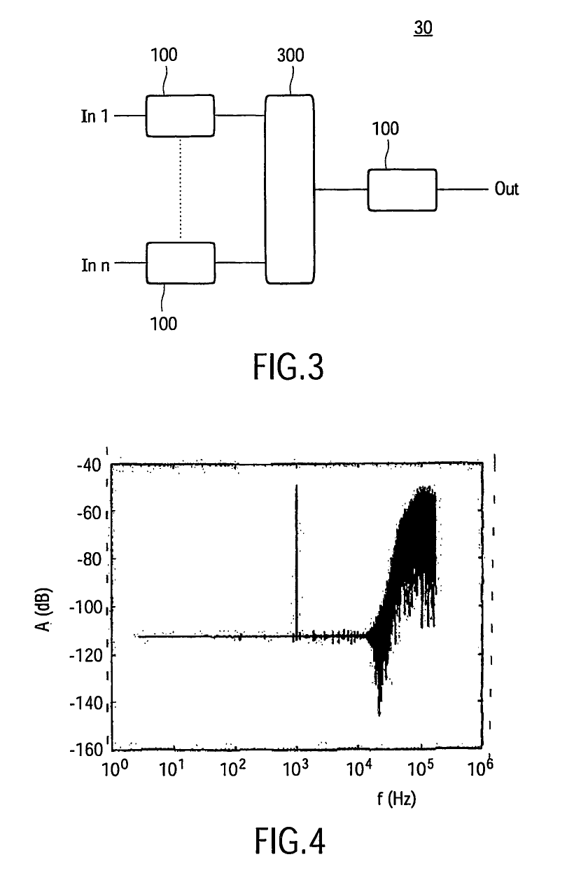

In a signal processing apparatus 30, as shown in FIG. 3, each individual signal, In_{1 . . . n} and Out (input and/or output) of signal processing unit 300 may be filtered by an adaptive low-pass filter 102. In this case, no signal is unnecessarily reduced in bandwidth

### EXAMPLE 1

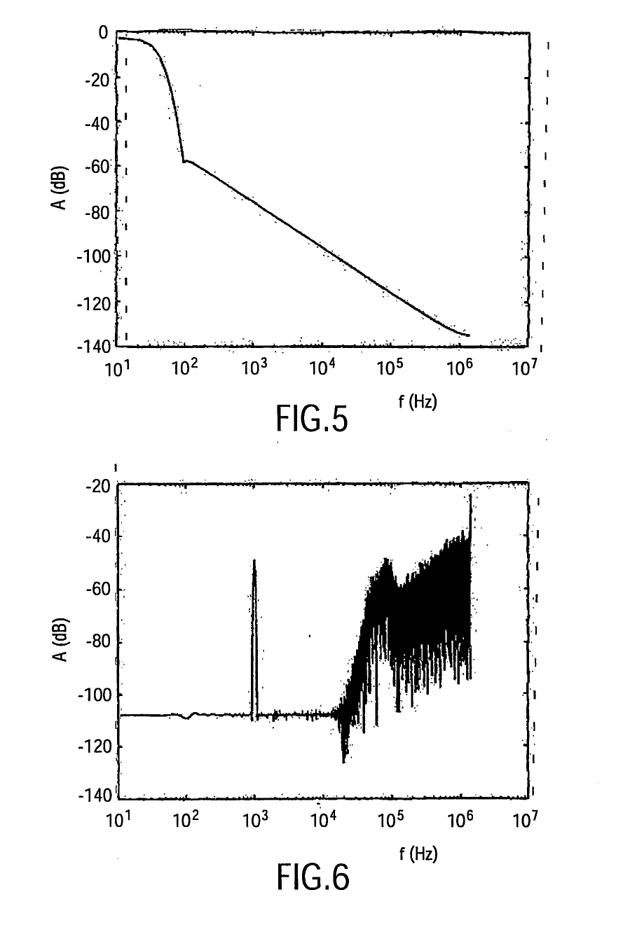

FIGS. 4 to 6 demonstrate the operation of the adaptive filtering device 100 of FIG. 2 or 3. FIG. 4 is a graph of the spectrum of a valid signal, obtained by adjusting the gain of a 1 kHz sine wave. FIG. 5 is a graph of the spectrum of the DSD stream that has been generated from the signal shown in FIG. 4. As shown in FIG. 5, not only is the sine wave with a frequency of 1 kHz gone, but the output signal does not contain any information, which indicates the SDM has been overloaded. FIG. 6 is a graph of the spectrum of the DSD stream that has been generated with the adaptive filtering device 100 of FIG. 2 or 3. The sine wave has been preserved and the output signal is valid for further editing and/or mastering.

While it is easy to design adaptive IIR filters, IIR filters cannot be used to implement the adaptive low-pass filter 102 of FIG. 2 because of their non-linear phase characteristic. The adaptive low-pass filter 102 may be implemented as one or more FIR filter structures, for example a linear phase, symmetric filter with constant length. The coefficients of the one or more FIR filter structures may be calculated on basis of the desired cut-off frequency of the one or more FIR filter structures.

The input data of the adaptive filtering device 100 may be processed in blocks using different exemplary techniques or algorithms. In a first exemplary algorithm, coefficients of the one or more FIR filter structures which make up the adaptive filtering device 100 are maintained constant for the duration of a block. Then, the last processed block or blocks are analyzed, and on basis of these results the cut-off frequency of the one or more FIR filter structures are adjusted. The next block will be filtered using the adjusted cut-of frequency and/or the modified coefficients. An advantage of this first exemplary algorithm is fast processing.

In a second exemplary algorithm, again coefficients of the one or more FIR filter structures which make up the adaptive filtering device 100 are maintained constant for the duration of a block. The cut-off frequency for the subsequent block is calculated on basis of the previous block or blocks. In the second exemplary algorithm, two or more FIR filter structures are used to make up the adaptive filtering device 100 and the filtered output of the adaptive filtering device 100 is composed of the combination of two or more filter outputs, one from each of the two or more FIR filter structures. In the second exemplary algorithm, a first of the two or more FIR filter structures has settings from the previous block and a second of the two or more FIR filter structures has the settings calculated for the current block. Further, the weighting ratio of the settings may be varied during one block period, resulting in a smoothly changing output. An advantage of the second exemplary algorithm is a reduction or absence of clicks in the adaptive filtering device 100 output.

A third exemplary algorithm is a combination of the first and second exemplary algorithms, where the second exemplary algorithm is implemented when clicks are imminent, otherwise the first exemplary algorithm is implemented.

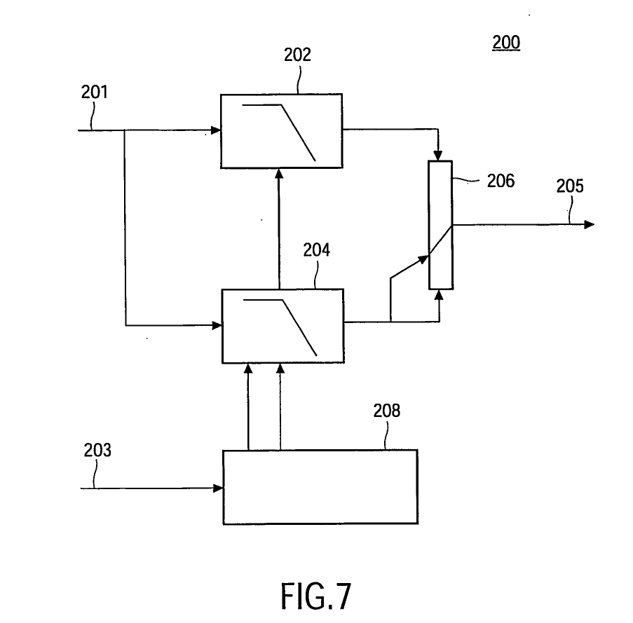

FIG. 7 illustrates the structure of an adaptive low-pass filtering device 200, in accordance with another exemplary embodiment of the present invention. FIG. 7 includes two or more adaptive filters 202, 204 (for example, low-pass, FIR filters of constant and equal length), a weighted adder 206, and a controller 208.

Inputs to the adaptive low-pass filtering device 200 may include the data 201 (for example, audio data) to be filtered and a cut-off frequency 203. An output is the filtered data 205 (for example, audio data). In an exemplary embodiment, the coefficients of the two or more adaptive filters 202, 204 are not fixed, but can vary and are calculated in the controller 208.

Exemplary operation of the adaptive low-pass filtering device 200 of FIG. 7 may be as follows. In order to achieve click-less switching, the adaptive low-pass filtering device 200 may be in either normal mode or in transition mode. In normal mode, the adaptive low-pass filtering device 200 is not changing filter characteristics. In transition mode the adaptive low-pass filtering device 200 is changing between different filter characteristics.

In normal mode, there is no cut-off transition in progress and only one FIR filter 202 is active and the output of the adaptive low-pass filtering device 200 includes the output of this single FIR filter 202. The cost of filtering is thus equal to the cost of one single FIR filter and the adaptive low-pass filtering device 200 is no more expensive than a single fixed FIR filter.

In transition mode, if a new cut-off frequency is selected, the controller 208 calculates filter weights that correspond to the new cut-off. The new filter weights are loaded in the inactive FIR (for example, in FIR filter 204). In order to achieve a click-less or substantially click-less transition and to reduce computational load, at least two exemplary switching scenarios may be used.

In a first exemplary switching scenario, if the change in cut-off frequency is small compared to the signal bandwidth or if the selected cut-off frequency is far above the audible audio range, instant changing between the two FIR filters 202, 204 may be performed without a high risk of introducing clicks or other distortions into the filtered data 205.

In a second exemplary switching scenario, if an instant change of coefficients is not acceptable, the two filters 202, 204 can be operated in parallel for a time. The filtered data 205 output from the adaptive low-pass filtering device 200 may then be slowly changed from a 100% weight of the first FIR filter 202 and 0% of the second FIR filter 204, to 0% of the first filter FIR 202 and 100% of the second FIR filter 204. By performing a gradual change between the two filters 202, 204, the filtered data 205 will not contain clicks and no distortion will be present. After the filter switching process has been completed, the first FIR filter 202 can be turned off and only the second FIR filter 204 will be necessary. It is noted that the function used to vary the weighting from 100% to 0% and vice versa, may be any mathematical function, for example, linear, exponential, etc. as would be known to one of ordinary skill in the art.

The switching process can be summarized as
calculate new filter coefficients and load them in the second filter,
enable the second filter,
change weighting of output from 1:0 to 0:1 in order to switch filters (instantly or gradually, depending on selected cut-off frequency and change in cut-off frequency), and
disable the first filter.

A result of the above described switching procedure, is that the cut-off frequency cannot change instantly for every combination of initial and ending cut-off frequency. However, the cross-over period does not need to be long, e.g. 1.45 ms is long enough for high-quality audio applications, and is therefore practically instantaneous.

Changing the cut-off frequency of an FIR low-pass filter is relatively complex since all the coefficients of the filter need to be recalculated. In general, calculating the coefficients of an FIR is time consuming and requires sin( ) operations or iterative search procedures, which are both expensive. In an exemplary embodiment, a window design method which does not need the usual sin( ) operations or iterative search loops is used, and can thus be relatively easy implemented in hardware. In an exemplary embodiment, the steps for calculating 2M+1 FIR coefficients (and their associated number of calculations) are as follows:
calculate initial (sin and cos) values using approximation formulas (required for the sine prediction filter. 8 multiplications, 5 additions), and
calculate coefficients using the sine prediction filter (M multiplications, M additions),
   apply a pre-calculated window function (M+1 multiplications),
   normalize the window for unity DC gain (M+2 multiplications, M additions, 1 division).

The cost for calculating the FIR is 3*M+11 multiplications, 2*M+5 additions and 1 division, which is about the same cost as calculating three output samples of a single FIR and thus almost negligible.

### EXAMPLE 2

By correctly choosing the number of filter taps and designing a matching window function, it is, for example, possible to create an adaptive low-pass filtering device that has only 13 filter taps but which can be tuned between a cut-off of 0.85π and 0.17π and that has less than 0.05 dB ripple between 0 and 0.057 π (corresponds to a cut-off between 150 kHz and 60 kHz that is flat (<0.05 dB) up to 20 kHz for a system running at 8×44100 Hz.

As described above, exemplary embodiments of the present invention provide the ability to control the signal energy in the high-frequency region, for example, in a desired range, below a desired maximum or maxima or above a desired minimum or minima.

As also described above, exemplary embodiments of the present invention provide the ability to switch between different low-pass filters without introducing clicks or other distortions in the filtered output and/or to generate filter coefficients in an efficient way with reduced computational load.

It is noted that the various exemplary embodiments of the present invention, including specific adaptive devices may be used singly or in any combination, as would be known to one of ordinary skill in the art. For example, the device of FIGS. 2, 3, and 7, may be used together in any combination.

It is further noted that the features of the present invention are usable with many types of filters, such as low-pass, band-pass, high-pass, FIR, active, passive, symmetric, asymmetric, constant length, and variable length.

The adaptive filters according to exemplary embodiments of the present invention may be included in an ADC and/or DD converter. Such an ADC and/or DD converter may be part of signal processing applications/devices for Super Audio CD (SACD) equipment, e.g. a player.

It is noted that the processing described above is particular useful in the processing of DSD.

It is further noted that that the input need not be restricted to a bitstream; the input may also be a (multi-bit) digital signal. It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claims. The word “comprising” does not exclude the presence of other elements or steps than those listed in a claim. The invention can be implemented by means of hardware comprising several distinct elements, and by means of a suitable programmed computer. In a device claim enumerating several means, several of these means can be embodied by one and the same item of hardware. The mere factor that certain measures are recited in mutually different dependent claims does not indicate that a combination of these measures cannot be used to advantage.

1. An adaptive filtering device (100), comprising:
at least one adaptive filter (102) for receiving an input signal (101); and
a metering device (104) for receiving an output (103) of the at least one adaptive filter (102), monitoring a characteristic of the output (103), and forwarding a correction signal (105) in a feedback loop to adjust the characteristic.

2. The adaptive filtering device (100) of claim 1, wherein the at least one adaptive filter is a low-pass filter, the metering device is a band-pass or high-pass filter and the characteristic is amount of high frequency in the output and the correction signal raises or lowers the high frequency cut-off of the low-pass filter.

3. The adaptive filtering device (100) of claim 1, wherein the adjusted characteristic is applied to the input signal block-by-block.

4. A signal processing device (30), comprising:
a signal processing unit (300) including at least one input and at least one output; and
the adaptive filtering device (100) of claim 1 for each of the at least one inputs and at least one outputs.

5. An adaptive filtering device (200), comprising:
at least two low-pass FIR filters (202, 204) for receiving an input signal (201),
a weighted adder (206) for receiving outputs from each of the at least two low-pass FIR filters (202, 204) and changing a weighting of each to produce filtered output data (205); and
a controller (208) for receiving at least one cut-off frequency (203), supplying the cut-off frequency (203) to the at least two low-pass FIR filters (202, 204), and supplying a signal to the weighted adder (206) for varying the weighting of each of the at least two low-pass FIR filters (202, 204) to switch between at least two low-pass FIR filters (202,204).

6. The adaptive filtering device (200) of claim 5, wherein the varied weighting is applied block-by-block.

7. The adaptive filtering device (200) of claim 5, wherein the adaptive filter device (200) operates in a normal mode and a transition mode, wherein the normal mode, the adaptive filter device (200) does not switch filter characteristics and the output of the adaptive filter device (200) is from only one of the at least two low-pass FIR filters (202, 204) and in the transition mode, the adaptive filter device 200 switches filter characteristics and the output of the adaptive filter device (200) is from more than one of the at least two low-pass FIR filters (202, 204).

8. The adaptive filtering device (200) of claim 7, wherein the transition mode, the controller (208) calculates new filter coefficients and loads the new filter coefficients into an unused low-pass FIR filter (204), enables the unused low-pass FIR filter (204), varies the weighting between at least one of the low-pass FIR filters (202) currently being used and the unused low-pass FIR filter (204) to switch therebetween, and disables the at least one of the low-pass FIR filters (204) currently being used.

9. The adaptive filtering device (200) of claim 8, wherein the controller (208) calculates the new filter coefficients by calculating initial sine and cosine values using an approximation formula and calculating coefficients using a sine prediction filter.

10. The adaptive filtering device (200) of claim 9, wherein the controller (208) calculates coefficients using the sine prediction filter by applying a pre-calculated window function and normalizing the window for unity DC gain.

11. A method of performing adaptive filtering, comprising:
receiving an output (103) of at least one adaptive filter (102),
monitoring a characteristic of the output, and
forwarding a correction signal (105) in a feedback loop to adjust the characteristic.

12. The method of claim 11, wherein the at least one adaptive filter (102) is a low-pass filter, and the characteristic is amount of high frequency in the output and the correction signal (105) raises or lowers the high frequency cut-off of the low-pass filter.

13. A method of performing adaptive filtering, comprising:
receiving outputs from at least two low-pass FIR filters (202, 204) and changing a weighting of each to produce filtered output data (205);
receiving at least one cut-off frequency (203), supplying the cut-off frequency (203) to at least one of the at least two low-pass FIR filters (202, 204); and
varying the weighting of each of the at least two low-pass FIR filters (202, 204) to switch between at least two low-pass FIR filters (202, 204).

14. The method of claim 13, wherein the method operates in a normal mode and a transition mode, wherein the normal mode, the method does not switch filter characteristics and the output is from only one of the at least two low-pass FIR filters (202) and in the transition mode, the method switches filter characteristics and the output is from more than one of the at least two low-pass FIR filters (202, 204).
